(19) United States
(12) Patent Application Publication
(10) Pub. No.: US 2014/0332047 A1
(43) Pub. Date: Nov. 13, 2014

(54) SERIAL AND PARALLEL CONNECTION STRUCTURES OF THERMAL TO ELECTRIC CONVERTING CELLS USING POROUS CURRENT COLLECTING MATERIAL AND APPLICATION OF THE SAME

(71) Applicant: Korea Institute of Energy Research, Daejeon (KR)

(72) Inventors: Sun-Dong KIM, Daejeon (KR); Jong-Hoon Joo, Chungcheongbuk-do (KR); Sang-Kuk Woo, Daejeon (KR); Se-Young Kim, Seongnam-si (KR); In-Sub Han, Daejeon (KR); Doo-Won Seo, Daejeon (KR); Min-Soo Suh, Daejeon (KR)

(73) Assignee: KOREA INSTITUTE OF ENERGY RESEARCH, Daejeon (KR)

(21) Appl. No.: 13/959,701

(22) Filed: Aug. 5, 2013

(30) Foreign Application Priority Data
May 10, 2013 (KR) 10-2013-0053360

(51) Int. Cl. H01L 35/10

(52) U.S. Cl. CPC H01L 35/10
USPC 136/205; 136/242

(57) ABSTRACT

Disclosed is a method for collecting current by using a liquefied or gaseous working fluid present inside an electric power generator system. Through the method, a porous structure like a metal felt capable of infusing the liquefied working fluid is inserted and connected to the cell, and then the working fluid present around the cell is naturally infused, so that current is collected. For this purpose, a current collector is provided, which is located between adjacent thermal to electric power generation cells among a plurality of the thermal to electric power generation cells.

### BACKGROUND

1. Field

The present invention relates to a method of configuring the power level of a system to have a desired capacity, and more particularly to serial and parallel connection structures of thermal to electric converting cells using a porous current collecting material and to the utilization of a power generator including the same.

2. Description of Related Art

Alkali metal thermal to electric converter (AMTEC) is a thermal to electric power generator capable of generating electrical energy from thermal energy.

When a temperature difference is given to both ends of an ionically conductive Beta-Alumina Solid Electrolyte (BASE), Na charged in the cell is ionized into Na+ due to the vapor pressure difference of Na and is diffused from anode to cathode through the electrolyte, and then is neutralized.

In this case, low voltage and high current are generated. So, when the cells are modularized by being connected in series or in parallel, a large amount of electric power can be generated.

The development of alkali metal thermal to electric converter (AMTEC) technology has started for the purpose of an electric power source for space. The AMTEC has a high power density per unit area and high efficiency, and maintains stability.

The AMTEC uses a variety of heat sources, for example, solar energy, fossil fuel, waste heat, terrestrial heat, nuclear reactor, etc. The AMTEC is comprised of electric power generation cells capable of generating electricity without using a driver such as a turbine, a motor or the like, so that it can directly generate electricity from a portion contacting with the heat. When the AMTEC is formed in the form of a module in series or in parallel, a great amount of electricity of several KW to several hundredths MW can be generated.

The form of waste heat includes flue gas, exhaust air, waste hot water, waste steam and the like. Sensible heat and reaction heat of a product of the production process are also classified into the waste heat. In the collection of the waste heat, there are a variety of forms, standards and materials, etc., of a heat exchanger which is applicable in accordance with the temperature of the waste heat, the condition of flow rate of the waste heat and whether or not the waste heat includes a corrosive material.

A device using the waste heat includes a waste heat collector, an electric heat exchanger, a heat pipe type heat exchanger and the like. In a special case, a separate collection system is considered.

The AMTEC is capable of improving the efficiency by directly generating high-quality electricity from the heat source. Therefore, the AMTEC is now issued as a promising technology replacing the existing power generation technologies, for example, hydro power generation, terminal power generation, nuclear power generation, tidal power generation, wind power generation and so on.

One of the features of the AMTEC power generation technology is to have a structure simpler than that of other thermoelectric conversion devices and to have high energy conversion efficiency.

In particular, compared with a solar thermal power plant, the AMTEC does not require a mechanical driving part like a turbine, etc. Compared with a thermoelectric device, the AMTEC can be applied to a high-capacity, high-efficiency system.

The process of generating electricity in the AMTEC will be specifically described. After the state of Na vapor is changed into a vapor state in a high temperature and high pressure evaporator by a heat source, Na+ passes through beta-alumina solid electrolyte (BASE), and free electrons return to a cathode through an electric load from an anode, and then are recombined with ion generated from the surface of a low temperature and low pressure BETA and then is neutralized. Electricity is generated during this process.

The vapor pressure of Na plays the most significant role in a thermal to electric power generator as an energy source or a driving force which generates electricity. Also, free electrons generated during a process in which Na passes through the solid electrolyte due to a concentration difference and temperature difference of a working fluid are collected through electrodes, so that electricity can be generated.

The beta-alumina and Na super-ionic conductor (NASICON) may be used as the solid electrolyte.

However, the NASICON has a problem in its stability of crystal structure when it is exposed to high temperature for a long time.

The beta-alumina includes two kinds of beta‘-alumina and beta”-alumina.

The beta“-alumina has a more improved layer structure so that the conductivity of the Na+ ion is much better. Therefore, the beta”-alumina is now generally used.

A process is repeated in which the neutral Na vapor is condensed by being cooled on the inner surface of a low pressure condenser and is transferred to an evaporator by a capillary wick, and then is changed into a vapor state again. Generally, the temperature of the evaporator is in a range of 900 K to 1,100 K, and the temperature of the condenser in a range of 500 K to 600 K.

It is possible for the efficiency of the thermal to electric power generation of the

AMTEC to be up to 40%. The AMTEC has a high power density and a simple structure without a separate driving part.

### PRIOR ART DOCUMENT

In Korean Patent Number 10-1240395, disclosed are a geothermal power generation system using heat exchange between a working fluid and molten salt and a method of the same, that is to say, disclosed are a geothermal power generation system capable of generating electricity by causing heat exchange between the working fluid and the molten salt in which waste heat or solar heat has been stored and a method of the same. More particularly, the geothermal power generation system using the heat exchange between the working fluid and molten salt includes: a heat collector; a plurality of molten salt receivers which receive the molten salt thereinside and are disposed apart from the ground by a regular interval; a heat exchanger which transfers the heat source of the heat collector to the molten salt of the molten salt receiver; a plurality of working fluid receivers which receive thereinside the working fluid receiving the heat source of the molten salt through the heat exchange, cover each of the molten salt receivers, and is disposed separately from the ground by a certain distance; a turbine which is connected to the working fluid receiver and generates mechanical energy by using steam energy generated by the working fluid receiver; and a power generator which is connected to the turbine and generates electrical energy by using the mechanical energy. However, there is still a requirement for a method of configuring the power level of a system to have a desired capacity.

### SUMMARY

### Technical Problem

In order to configure the power level of the AMTEC system to have a desired capacity, attempts are being made to increase the capacity of a unit cell itself and to increase the voltage and current of the system by configuring in series or in parallel a plurality of the cells.

In the manufacture of a high capacity AMTEC system, a conventional method for increasing the capacity of the unit cell itself includes a difficult process of manufacturing a large instrument and a possibility of being mechanically fragile, and requires expensive equipments needed for production.

Although a large unit cell has been manufactured, the exchange or repair of the large cell at the time of breakdown of the system requires a high cost. Therefore, the system is configured to have a desired capacity by stacking small cells.

As shown in FIG. 6, the conventional method is to collect current in the unit cell in the manner of winding a cylindrical cell by using a coil-type current collector, and then to form a serial or parallel stack in the way of combining wires for collecting current. However, in the conventional method, the combination of the wires is difficult to reproduce, and much time and effort is required for winding the wires to combine the wires. Also, there is a possibility that the wire is short-circuited, and when a large amount of current is provided, very thick wire or a plurality of wires are necessary, so that it is difficult to form a circuit.

### Technical Solution

One aspect of the present invention is a method for collecting current by using a liquefied or gaseous working fluid present inside an electric power generator system. Through the method, a porous structure like a metal felt capable of infusing the liquefied working fluid is inserted and connected to the cell, and then the working fluid present around the cell is naturally infused, so that current is collected.

For this purpose, a current collector is used, which is located between adjacent thermal to electric power generation cells and electrically connects the cells.

More specifically, the method may include a first thermal to electric power generation cell among a plurality of the thermal to electric power generation cells, a second thermal to electric power generation cell adjacent to the first thermal to electric power generation cell, and the current collector which is located between the first and the second thermal to electric power generation cells and electrically connects them.

It is possible to configure a serial current collector in which the cathode (+) and anode (−) of parallel current collection structures of the plurality of the thermal to electric power generation cells are connected in series.

### ADVANTAGEOUS EFFECTS

A porous structure itself like a metal felt has a high electrification property and buffering effect, and thus, can be used as a common electric current collector.

When liquid metal is absorbed into the inside of a porous material, interfacial resistance between the cells becomes very low due to wet contact, the current collecting effect can be maximized.

Moreover, the method of the present invention does not need complex wires, makes it easier to generate a large amount of electric power at a low cost thanks to a simple structure, is mechanically stable and is applicable regardless of a large amount of the current.

Also, the method has high current collection efficiency, collects current regardless of the amount of the current, and has no short-circuit.

Finally, working fluid steam and liquid which are present during the operation of the method can be used.

### BRIEF DESCRIPTION OF THE DRAWINGS

FIG. 1 shows a parallel current collection structure and a serial current collector in accordance with the present invention;

FIG. 2 is a diagram showing a principle of operation of a unit thermal to electric power generator in accordance with the present invention;

FIG. 3 is a diagram showing a principle of operation of a thermal to electric power generator in accordance with the present invention;

FIG. 4 shows a thermal to electric power generation cell according to the present invention;

FIG. 5 is a diagram showing the parallel current collection structure and a principle of collecting current of the serial current collector in accordance with the present invention; and

FIG. 6 is a diagram view showing a principle of collecting current by a conventional method.

### DETAILED DESCRIPTION

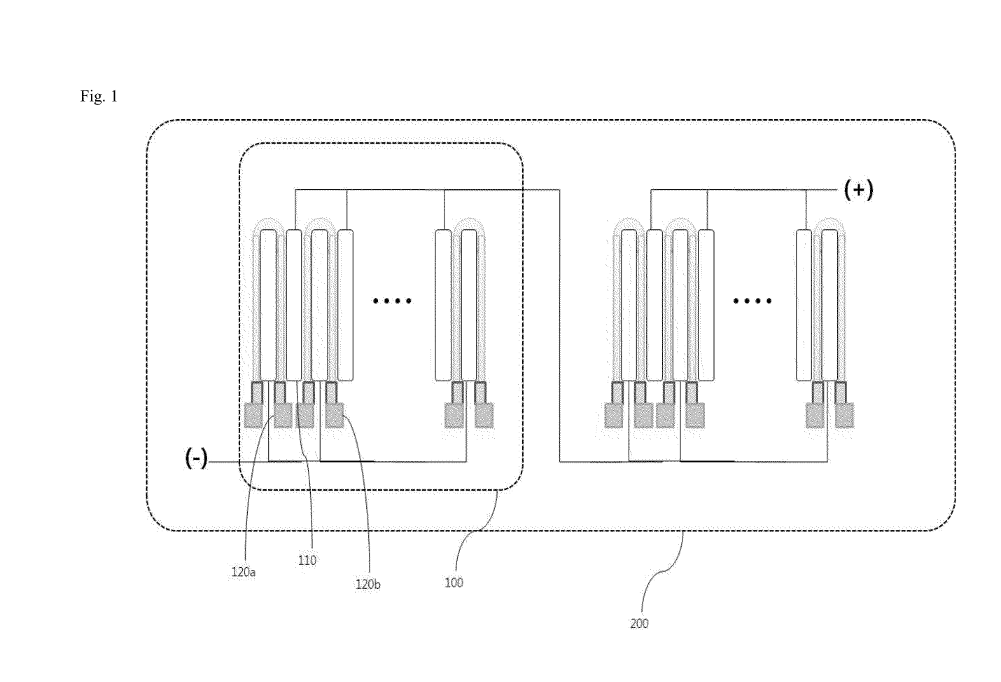

FIG. 1 shows a parallel current collection structure and a serial current collector in accordance with the present invention.

A current collector 110, which is located between adjacent thermal to electric power generation cells 120 and electrically connects the cells, has a porous structure.

The current collector 110 may have a shape in which a quadrangular metal surface having a porous felt shape is wounded in the structure of a roll.

The current collector 110 may also have a cylindrical shape with an empty interior or may have a felt shape of which all the sides are porous. However, the shape of the current collector 110 is not limited to this.

It is preferable that the current collector 110 is made of a metallic material having elasticity and conductivity and includes at least one of Mo, Ti, W, Cu, Ni, Fe, and Cr.

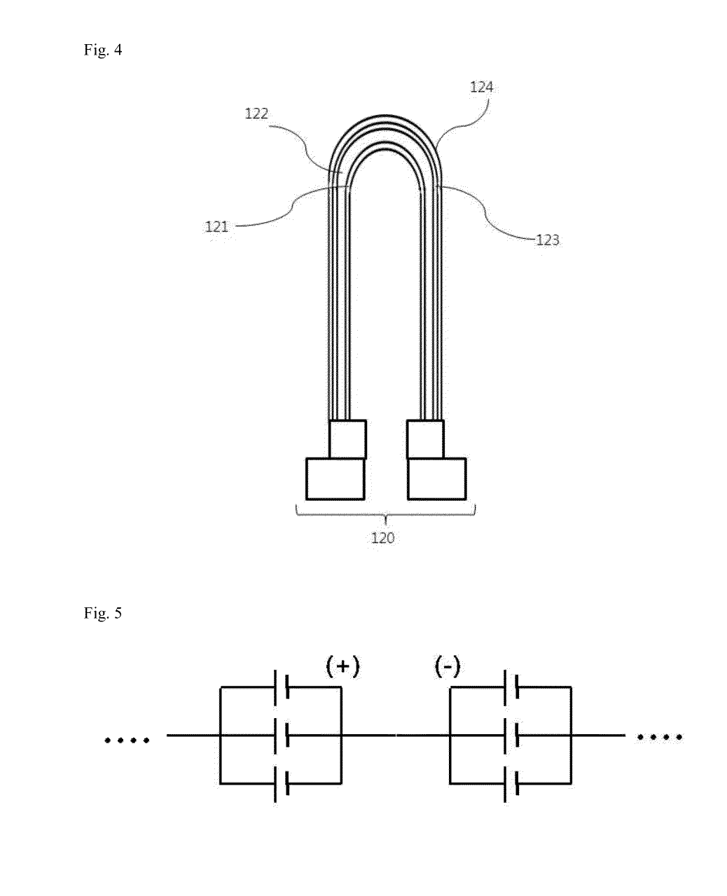

FIG. 4 shows the thermal to electric power generation cell 120 according to the present invention.

The thermal to electric power generation cell 120 may include a tubular metal support 122, a porous internal electrode 121 formed on the inner surface of the tubular metal support 122, a solid electrolyte 123 formed on the outer surface of the tubular metal support 122, and a porous external electrode 124 formed on the surface of the solid electrolyte 123.

The metal support 122 and the internal electrode 121 formed on the inner surface of the metal support 122 may be integrally formed. That is, the internal electrode 121 functioning as the metal support 122 may be formed and used.

The metal support 122 is a porous metal support. The support 122 may include at least any one of Mo, Ti, W, Cu, Ni, Fe, Ni—Fe, stainless, and bronze.

The solid electrolyte 123 may include at least any one of a beta-alumina solid electrolyte and a Na super-ionic conductor (NASICON) solid electrolyte.

It is the most preferable to use the beta-alumina solid electrolyte. As shown in FIG. 1, a parallel current collection structure 100 of a plurality of the thermal to electric power generation cells 120 may include a first thermal to electric power generation cell 120a among a plurality of the thermal to electric power generation cells 120, a second thermal to electric power generation cell 120b adjacent to the first thermal to electric power generation cell 120a, and the current collector 110 which is located between the first and the second thermal to electric power generation cells 120a and 120b and electrically connects them.

In a serial current collector 200 including the parallel current collection structure 100 of the plurality of the thermal to electric power generation cells 120, the cathode (+) and anode (−) of the parallel current collection structures 100 of the plurality of the thermal to electric power generation cells 120 may be connected in series.

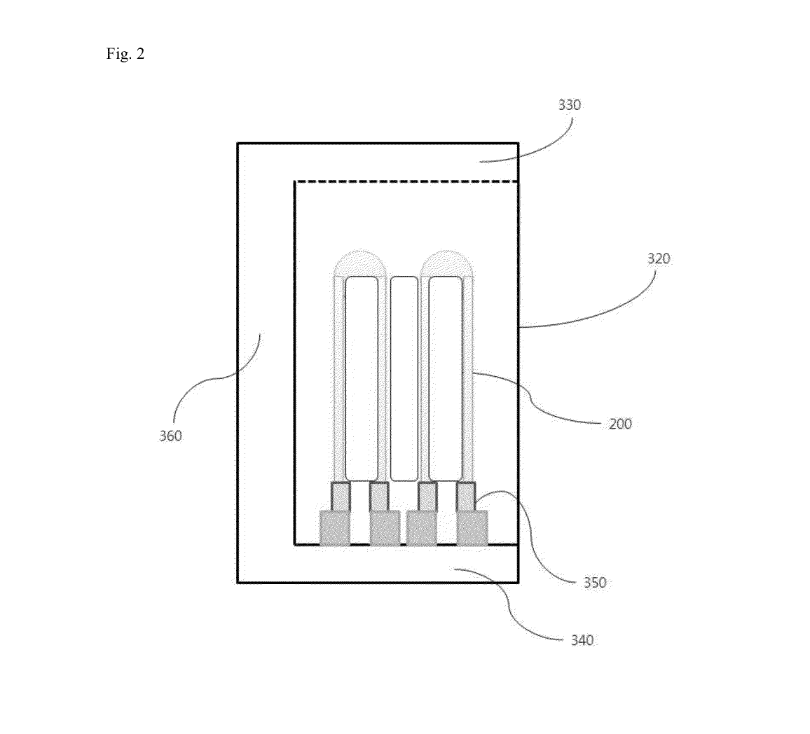

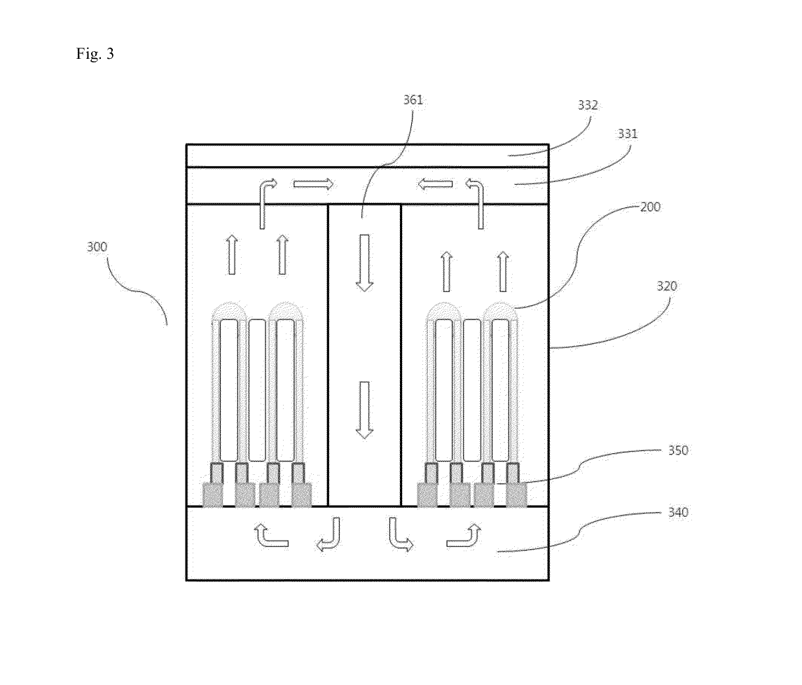

FIG. 2 is a diagram showing a principle of operation of a unit thermal to electric power generator in accordance with the present invention.

A thermal to electric power generator 300 including the plurality of the thermal to electric power generation cells 120 may include the serial current collector 200; a case 320 in which the serial current collector 200 is placed; a condensing unit 330 which is disposed on an upper portion of the case 320 and collects and condenses a working fluid which has passed through the thermal to electric power generation cell 120 of the serial current collector 200; an evaporator 340 which is disposed on a lower portion of the case 320, converts the working fluid into vapor by transferring heat to the working fluid and then transfers the working fluid vapor to the thermal to electric power generation cell 120 of the serial current collector 200; a circulator 360 which connects the condensing unit 330 and the evaporator 340 to thereby allow the working fluid to be transferred; a joiner 350 which joins the evaporator 140 to the thermal to electric power generation cell 120 of the serial current collector 200; and a heat source which heats the lower portion of the case 320.

It is preferable that the joiner 350 includes an insulating alpha-alumina and a metal ring which is placed under the alpha-alumina and improves the joinability with the evaporator 340.

The working fluid may include at least any one of Na, K, and Li. It is the most preferable that the working fluid includes Na. However, there is no limit to this.

The condensing unit 330 may include a capillary wick 331 and a condenser 332. The low temperature-low pressure working fluid passes through the capillary wick 331. The condenser 332 is located on the capillary wick 331.

The circulator 360 may correspond to a capillary circulation wick 361 connected to the condensing unit 330.

FIG. 5 is a diagram showing the parallel current collection structure and a principle of collecting current of the serial current collector in accordance with the present invention.

When one parallel current collection structure of the serial current collector represents (+), the other parallel current collection structure represents (−). Consequently, the one parallel current collection structure represents (+) and (−).

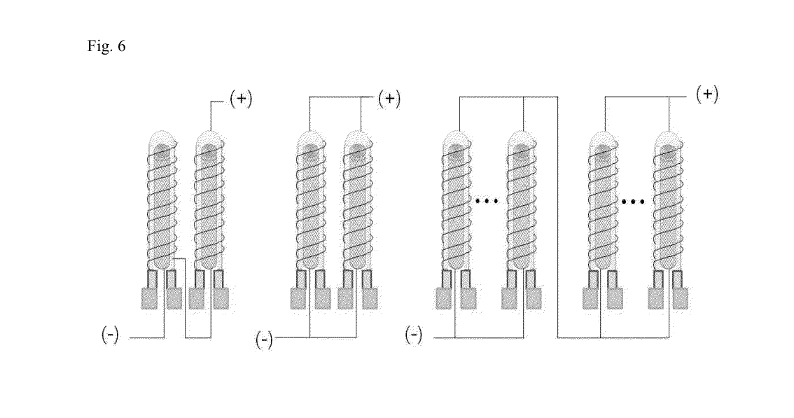

FIG. 6 is a diagram view showing a principle of collecting current by a conventional method.

In the past, the conventional method is to collect current in a unit cell in the manner of winding a cylindrical cell by using a coil-type current collector, and then to form a serial or parallel stack in the way of combining wires for collecting current.

However, in the conventional method, the combination of the wires is difficult to reproduce, and much time and effort is required for winding the wires to combine the wires. Also, there is a possibility that the wire is short-circuited, and when a large amount of current is provided, very thick wire or a plurality of wires are necessary, so that it is difficult to form a circuit.

The present invention provides a method for collecting current by using a liquefied or gaseous working fluid present inside an electric power generator system. Through the method, a porous structure like a metal felt capable of infusing the liquefied working fluid is inserted and connected to the cell, and then the working fluid present around the cell is naturally infused, so that current is collected.

The porous structure itself like the metal felt has a high electrification property and buffering effect, and thus, can be used as an electric current collector.

When liquid metal is absorbed into the inside of a porous material, interfacial resistance between the cells becomes very low due to wet contact, the current collecting effect can be maximized.

Moreover, the method of the present invention has a simple structure easy to obtain at a low cost, is mechanically stable and is applicable regardless of a large amount of the current.

Accordingly, working fluid steam and liquid which are present during the operation of the method can be used.

The present invention has been described with reference to the accompanying drawings. This is just one of various embodiments including the subject matter of the present invention and intends to allow those skilled in the art to easily embody the present invention. It is clear that the present invention is not limited to the above-described embodiments. Therefore, the scope of the present invention should be construed by the following claims. Without departing from the subject matter of the present invention, all the technical spirits within the scope equivalent to the subject matter of the present invention is included in the right scope of the present invention by the modifications, substitutions, changes and the like. Also, it is clear that some of the drawing configuration are intended for more clearly describing the configuration and are more exaggerated or shortened than the actual one.

What is claimed is:

1. A current collector which is located between adjacent thermal to electric power generation unit cells and electrically connects the cells, the current collector comprising a porous structure.

2. The current collector of claim 1, wherein the current collector has a shape in which a quadrangular metal surface having a porous felt shape is wounded in the structure of a roll.

3. The current collector of claim 1, wherein the current collector has a cylindrical shape with an empty interior or a felt shape of which all the sides are porous.

4. The current collector of claim 1, wherein the current collector is made of a metallic material having elasticity and conductivity, and comprises at least one of Mo, Ti, W, Cu, Ni, Fe, and Cr.

5. The current collector of claim 1, wherein the thermal to electric power generation unit cell comprises:
a tubular metal support;
a porous internal electrode formed on an inner surface of the tubular metal support;
a solid electrolyte formed on an outer surface of the tubular metal support; and
a porous external electrode formed on a surface of the solid electrolyte.

6. A parallel current collection structure of a plurality of thermal to electric power generation unit cells, the parallel current collection structure comprising:
a first thermal to electric power generation unit cell among the plurality of the thermal to electric power generation unit cells;
a second thermal to electric power generation unit cell adjacent to the first thermal to electric power generation unit cell; and
the current collector of claim 1, which is located between the first and the second thermal to electric power generation unit cells and electrically connects them.

7. A serial current collector comprising the parallel current collection structure of the plurality of the thermal to electric power generation unit cells of claim 6, wherein a cathode (+) and an anode (−) of the parallel current collection structures of the plurality of the thermal to electric power generation unit cells of claim 6 are connected in series.

8. A thermal to electric power generator comprising plurality of thermal to electric power generation unit cells, the thermal to electric power generator comprising:
the serial current collector of claim 7;
a case in which the serial current collector is placed;
a condensing unit which is disposed on an upper portion of the case and collects and condenses a working fluid which has passed through the thermal to electric power generation unit cell of the serial current collector;
an evaporator which is disposed on a lower portion of the case, converts the working fluid into vapor by transferring heat to the working fluid and then transfers the working fluid vapor to the thermal to electric power generation unit cell of the serial current collector;
a circulator which connects the condensing unit and the evaporator to thereby allow the working fluid to be transferred;
a joiner which joins the evaporator to the thermal to electric power generation unit cell of the serial current collector; and
a heat source which heats the lower portion of the case.

9. The thermal to electric power generator of claim 8, wherein the joiner comprises an insulating alpha-alumina and a metal ring which is placed under the alpha-alumina and improves joinability with the evaporator.

10. The thermal to electric power generator of claim 8, wherein the working fluid comprises at least any one of Na, K, and Li.

11. The thermal to electric power generator of claim 8, wherein the condensing unit comprises a capillary wick through which a low temperature-low pressure working fluid passes, and a condenser located on the capillary wick.
